(19) United States
(12) Patent Application Publication
(10) Pub. No.: US 2025/0377591 A1
(43) Pub. Date: Dec. 11, 2025

(54) PHOTORESIST COMPOSITION AND METHOD FOR FABRICATING SEMICONDUCTOR DEVICE

(71) Applicant: Samsung Electronics Co., Ltd., Suwon-si (KR)

(72) Inventors: Sungan Do, Suwon-si (KR); Seungchul Kwon, Suwon-si (KR); Min Sang Kim, Suwon-si (KR); Hana Kim, Suwon-si (KR); Yonghoon Moon, Suwon-si (KR); Chanjae Ahn, Suwon-si (KR); Sungwon Choi, Suwon-si (KR)

(21) Appl. No.: 19/171,606

(22) Filed: Apr. 7, 2025

(30) Foreign Application Priority Data
Jun. 5, 2024 (KR) 10-2024-0074028

(51) Int. Cl. G03F 7/038; C09D 167/04; G03F 7/00; G03F 7/039

(52) U.S. Cl. CPC G03F 7/0384; C09D 167/04; G03F 7/0382; G03F 7/0388; G03F 7/0392; G03F 7/70033

(57) ABSTRACT

A photoresist composition is provided. The photoresist composition includes a photosensitive polymer, a photoacid generator, and a solvent. The photosensitive polymer can include a first main chain group, a second main chain group, and an acid-dissociative group attached to the first main chain group, and at least one of the first main chain group or the second main chain group comprises an acid-dissociative functional group which is cleaved between the first main chain group and the second main chain group and between the first main chain group and the acid-dissociative group under presence of an acid catalyst.

### CROSS-REFERENCE TO RELATED APPLICATIONS

This application claims priority under 35 U.S.C. § 119 to Korean Patent Application No. 10-2024-0074028, filed on Jun. 5, 2024, in the Korean Intellectual Property Office, the disclosure of which is incorporated by reference herein in its entirety.

### FIELD

Embodiments of the present disclosure described herein relate to a photoresist composition and a method for fabricating a semiconductor device, and more particularly, relate to a photoresist composition including a photosensitive polymer and a method for fabricating a semiconductor device using the same.

### BACKGROUND

Recently, as electron technology has developed, semiconductor devices in smaller size have been rapidly developed. To realize semiconductor devices in smaller sizes, a photolithography process has been required to form a fine pattern. In particular, t developing a technology for improving solubility contrast for a developer between an exposed area and a non-exposed area of a photoresist layer in a photolithography process is needed.

### SUMMARY

Embodiments of the present disclosure provide a photoresist composition capable of improving solubility contrast for a developer between an exposed area and a non-exposed area of a photoresist layer.

Embodiments of the present disclosure provide a photoresist composition capable of improving solubility contrast for a developer between an exposed area and a non-exposed area of a photoresist layer in a photolithography process to fabricate a semiconductor device.

According to an embodiment of the present disclosure, a photoresist composition includes a photosensitive polymer, a photoacid generator, and a solvent. The photosensitive polymer includes a first main chain group, a second main chain group, and an acid-dissociative group attached to the first main chain group. At least one of the first main chain group or the second main chain group comprises an acid-dissociative functional group which is cleaved between the first main chain group and the second main chain group and between the first main chain group and the acid-dissociative group under presence of an acid catalyst.

According to an embodiment of the present disclosure, the photosensitive polymer, which is a chemical-amplification photosensitive polymer, includes a first main chain group, a second main chain group, and an acid-dissociative group attached to the first main chain group. At least one of the first main chain group or the second main chain group comprises an acid-dissociative functional group which is cleaved between the first main chain group and the second main chain group and between the first main chain group and the acid-dissociative group under presence of an acid catalyst. The photosensitive polymer includes a repeating unit of Chemical Formula 1.

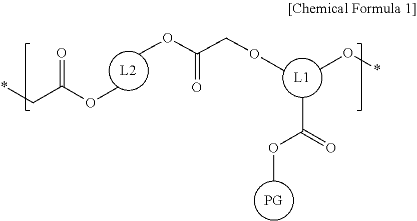

In which L1 is a trivalent substituted or unsubstituted aliphatic or aromatic hydrocarbon having 1 to 20 carbon atoms, L2 is a divalent substituted or unsubstituted aliphatic or aromatic hydrocarbon having 1 to 20 carbon atoms, PG, which serves as a protecting group, is hydrogen or a monovalent substituted or unsubstituted aliphatic or aromatic hydrocarbon having 1 to 10 carbon atoms, and * is an attachment position.

According to an embodiment of the present disclosure, a method for fabricating a semiconductor device includes forming a photoresist layer on an underlayer, exposing a first area of the photoresist layer, forming a photoresist pattern by removing the first area of the photoresist layer using a developer, and processing the underlayer using the photoresist pattern. The photoresist layer includes a photosensitive polymer, a photoacid generator, and a solvent. The photosensitive polymer includes a first main chain group, a second main chain group, and an acid-dissociative group attached to the first main chain group. At least one of the first main chain group or the second main chain group comprises an acid-dissociative functional group which is cleaved between the first main chain group and the second main chain group and between the first main chain group and the acid-dissociative group under presence of an acid catalyst.

### BRIEF DESCRIPTION OF THE FIGURES

The above and other objects and features of the present disclosure will become apparent by describing in detail embodiments thereof with reference to the accompanying drawings.

FIG. 1 is a flowchart illustrating an example method for fabricating an integrated circuit device according to an embodiment of the present disclosure.

FIGS. 2A to 2E are cross-sectional views illustrating a method for fabricating an integrated circuit device in a process sequence according to an example embodiment of the present disclosure.

FIG. 3 is a graph illustrating, as an exposure dose, a thickness of an exposed part, which remains after development, when forming a photoresist layer on an underlayer using a photoresist composition according to an example embodiment of the present disclosure.

### DETAILED DESCRIPTION

While the present disclosure is susceptible to various modifications and alternative forms, specific embodiments thereof are shown by way of example in the drawings and will be described herein in detail. It should be understood, however, that there is no intent to limit the present disclosure to the particular forms disclosed, but on the contrary, the present disclosure is to cover all modifications, equivalents, and alternatives falling within the spirit and scope of the present disclosure.

According to an embodiment of the present disclosure, the photoresist composition includes a photosensitive polymer, a photoacid generator (PAG), and a solvent.

The photosensitive polymer may induce a photochemical reaction, as extreme ultraviolet (EUV) light is irradiated to the photosensitive polymer. For example, the photosensitive polymer may induce a photochemical reaction, as a KrF excimer laser beam (248 nm), an ArF excimer laser beam (193 nm), an F2 excimer laser beam (157 nm), or an EUV laser beam (135 nm) is irradiated to the photosensitive polymer.

According to an embodiment of the present disclosure, the solubility of the photosensitive polymer for the developer may be increased, as a specific portion of the photosensitive polymer is cleaved through the photochemical reaction. The photosensitive polymer may include a functional group which is provided in a repeating unit of a main chain and cleaved by using acid which is generated in an exposure step as a catalyst. In addition, the photosensitive polymer may include a protecting group which is provided in the repeating unit of the main chain and cleaved by using acid, which is generated in the exposure step, as a catalyst. The photosensitive polymer may have an acid-dissociative functional group provided in the repeating unit of the main chain, and attached between the main chain and the protecting group, and the acid-dissociative functional group may be decomposed by using the acid, which is generated in the exposure step, as the catalyst. Accordingly, the repeating unit of the main chain may be cleaved into at least two groups, and the protecting group may undergo deprotection. In some embodiments, in the exposure step, the reaction of cleaving the repeating unit of the main chain and the reaction of dissociating the protecting group may be independently performed. In some embodiments, the photosensitive polymer is changed in polarity and molecular weight through the reaction of cleaving the repeating unit of the main chain and the reaction of dissociating the protecting group, such that the photosensitive polymer may be sufficiently dissolved in the developer. In addition, the protecting group undergoing deprotection may generate new acid to perform a chemical amplification action.

Chemical Equation 1 schematically shows the decomposition procedure of the photosensitive polymer according to the present disclosure. In the following Chemical Formula, is an attaching position.

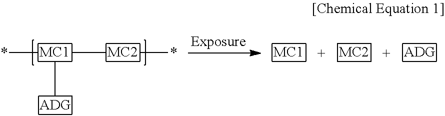

In Chemical Equation 1, the photosensitive polymer, which serves as a main chain, may have repeating units including two main chain groups, for example, a first main chain group MC1 and a second main chain group MC2. Hereinafter, for the convenience of explanation, the repeating unit of the photosensitive polymer includes two main chain groups by way of example. However, the repeating unit of the photosensitive polymer is not limited thereto. For example, the repeating unit may include three main chain groups.

The first main chain group MC1 and the second main chain group MC2 may be the same groups or may be mutually different groups. The photosensitive polymer may be copolymers in which the first main chain group MC1 and the second main chain group MC2 are repeated. Each of the first main chain group MC1 and the second main chain group MC2 may be a monomer, a dimer, an oligomer, or a polymer. An acid-dissociative group ADG may be attached to at least one of the first main chain group MC1 and the second main chain group MC2. Chemical Equation 1 shows the acid-dissociative group ADG attached to the first main chain group MC1. The following description will be made with reference to the acid-dissociative group ADG attached to the first main chain group MC1 by way of example.

As the photosensitive polymer is exposed to light, the first main chain group MC1 and the second main chain group MC2 may be cleaved from each other, and the first main chain group MC1 and the acid-dissociative group ADG may be cleaved from each other, in the photosensitive polymer. In some embodiments, reaction products may be produced to correspond to the first main chain group MC1, the second main chain group MC2, and the acid-dissociative group ADG through the cleavage.

As the photosensitive polymer is exposed to the light, the first main chain group MC1, the second main chain group MC2, and the acid-dissociative group ADG may be cleaved through an acid-catalyst reaction. Although Chemical Equation 1 shows that the first main chain group MC1 is simply bonded to the second main chain group MC2, and the first main chain group MC1 is simply bonded to the acid-dissociative group ADG, functional groups (e.g., acid-dissociative functional groups), which are decomposed by an acid catalyst, may be attached between the first main chain group MC1 and the second main chain group MC2 and between the first main chain group MC1 and the acid-dissociative group ADG. The functional group, which is decomposed by the acid catalyst, may include an ester or amide. The acid catalyst may be produced from a photoacid generator.

The acid-dissociative group ADG may be dissociated from the first main chain group MC1 under the acid catalyst generated in the exposure process. The acid-dissociative group ADG may produce carboxylic acid, when the acid-dissociative group ADG is dissociated under the acid catalyst by photoacid generated in the exposure process. In some embodiments, the polarity of the first main chain group MC1 may be changed by carboxylic acid generated in the dissociation procedure. Carboxylic acid may increase the hydrophilicity of the photosensitive polymer to increase the difference in polarity between the non-exposed area and the photosensitive polymer. Accordingly, as the acid-dissociative group ADG is dissociated from the first main chain group MC1 in the exposed area, the difference in polarity of the photosensitive polymer may be increased between the exposed area and the non-exposed area. The polarity of the exposed area may be increased to increase the solubility for the developer. The second main chain group MC2 is dissociated from the first main chain group MC1 under acid catalyst by photoacid generated in the exposure process, and the whole molecular weight of the photosensitive polymer is reduced.

The polarity of the reaction product in the exposure process may be varied depending on a functional group between the first main chain group MC1 and the second main chain group MC2, and/or a functional group provided between the first main chain group MC1 and the acid-dissociative group ADG. In addition, the molecular weight of the reaction product in the exposure process may be varied depending on the type and the structure of the first main chain group MC1 and the second main chain group MC2.

In some embodiments, the molecular weight and the polarity of the photosensitive polymer are changed as the photosensitive polymer is exposed to light. Accordingly, the reaction product after the exposure process may be easily dissolved.

According to an embodiment of the present disclosure, the photosensitive polymer may be a polymer having a repeating unit shown in following Chemical Formula 1.

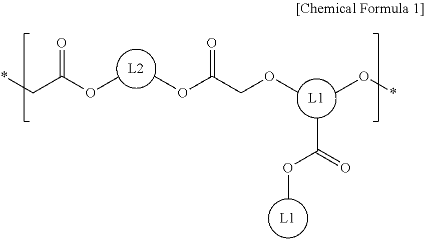

L1 may be a trivalent aliphatic hydrocarbon group or a trivalent aromatic hydrocarbon group. The trivalent aliphatic hydrocarbon group may have a saturated or unsaturated structure.

For example, L1 may be a single bond or a substituted or unsubstituted alkylene group having 1 to 20 carbon atoms. According to an embodiment, L1 may be a substituted or unsubstituted alkylene group having 1 to 10 carbon atoms or a substituted or unsubstituted alkylene group having 1 to 5 carbon atoms. The term “substituted” may refer to substitution with an alkyl group (e.g., CCF₃, CHCF₂, CH₂F, CCl₃) having 1 to 10 carbon atoms substituted with a halogen atom, a hydroxy group, a nitro group, a cyano group, an amino group, an amidino group, a hydrazine, a hydrazone, a sulfonic acid group or a salt thereof, a phosphoric acid or a salt thereof, or an alkyl group having 1 to 10 carbon atoms, an alkenyl group having 2 to 10 carbon atoms, an alkynyl group having 2 to 10 carbon atoms, a cycloalkyl group having 3 to 20 carbon atoms, a heterocycloalkyl group having 3 to 20 carbon atoms, an aryl group having 6 to 20 carbon atoms, an arylalkyl group having 6 to 20 carbon atoms, a heteroaryl group having 6 to 20 carbon atoms, or a heteroarylalkyl group having 6 to 20 carbon atoms.

The alkyl group is a branched or unbranched (or straight-chain or linear) hydrocarbon group which is fully saturated. A non-limiting example of the alkyl groups may include methyl, ethyl, n-propyl, isopropyl, n-butyl, isobutyl, sec-butyl, n-pentyl, isopentyl, neopentyl, iso-amyl, n-hexyl, 3-methylhexyl, 2,2-dimethylpentyl, 2,3-dimethylpentyl, or n-heptyl. At least one hydrogen atom in the above alkyl group may be substituted as described above with a substituent disclosed above.

The alkenyl group refers to an aliphatic hydrocarbon containing at least one double bond. The alkynyl group refers to an aliphatic hydrocarbon containing at least one triple bond.

The cycloalkyl group refers to an aliphatic hydrocarbon containing at least one ring. In this case, the alkyl group has been described above.

The heterocycloalkyl group refers to a cycloalkyl group containing at least one heteroatom selected from N, O, P, or S. In this case, the cycloalkyl group has been described above.

The aryl group refers to an aromatic hydrocarbon used alone or in a combination form and including at least one ring. The aryl group can include a group in which an aromatic ring is fused to at least one cycloalkyl ring. A non-limiting example of the above aryl group includes a phenyl group, a naphthyl group, or a tetrahydronaphthyl group. In addition, at least one hydrogen atom of the above aryl group may be substituted with a substituent similar to that of the alkyl group described above.

The arylalkyl group represents “alkyl group-aryl group-”, in which the alkyl group and the aryl group have been described above.

The heteroaryl group refers to a monocyclic or bicyclic organic compound containing at least one heteroatom selected from N, O, P or S, and having carbon as a reaming ring atom. The heteroaryl group may contain, for example, 1 to 5 heteroatoms and 5 to 10 ring members. The S or N may be oxidized to have various oxidation states. The monocyclic heteroaryl group may include, for example, a thienyl group, a furyl group, a pyrrolyl group, an imidazolyl group, a pyrazolyl group, a thiazolyl group, an isothiazolyl group, an 1,2,3-oxadiazolyl group, an 1,2,4-oxadiazolyl group, an 1,2,5-oxadiazolyl group, an 1,3,4-oxadiazolyl group, an 1,2,3-thiadiazolyl group, an 1,2,4-thiadiazolyl group, an 1,2,5-thiadiazolyl group, an 1,3,4-thiadiazolyl group, an isothiazol-3-yl group, an isothiazol-4-yl group, an isothiazol-5-yl group, an oxazol-2-yl group, an oxazol-4-yl group, an oxazol-5-yl group, an isoxazol-3-yl group, an isoxazol-4-yl group, an isoxazol-5-yl, an 1,2,4-triazol-3-yl group, an 1,2,4-triazol-5-yl group, a 1,2,3-triazol-4-yl group, a 1,2,3-triazol-5-yl group, a tetrazolyl group, a pyrid-2-yl group, a pyrid-3-yl group, a 2-pyrazin-2-yl group, a pyrazin-4-yl group, a pyrazin-5-yl group, a 2-pyrimidin-2-yl group, a 4-pyrimidin-2-yl group, or a 5-pyrimidin-2-yl group. The heteroaryl group includes a heteroaromatic ring which is fused to at least one of aryl, cycloaliphatic, or heterocycle. The bicyclic heteroaryl group includes, for example, an indolyl group, an isoindolyl group, an indazolyl group, an indolizinyl group, a purinyl group, a quinolizinyl group, a quinolinyl group, or an isoquinolinyl group. At least one hydrogen atom of such heteroaryl group may be substituted with a substitutent, similarly to the alkyl group described above.

The heteroarylalkyl group represents “alkyl group-heteroaryl group-”, in which the aryl group has been described above. The heteroaryloxy group represents “heteroaryl group-O—”, in which the heteroaryl group has been described above.

L2 may be a divalent aliphatic hydrocarbon group or a divalent aromatic hydrocarbon group. The divalent aromatic hydrocarbon group may have a saturated or unsaturated structure.

For example, L2 may be a single bond or a substituted or unsubstituted alkylene group having 1 to 20 carbon atoms. According to an embodiment, ‘L2’ may be a substituted or unsubstituted alkylene group having 1 to 10 carbon atoms or a substituted or unsubstituted alkylene group having 1 to 5 carbon atoms. In this case, the term “substitution” may refer to a halogen atom substituted with an alkyl group (e.g., CCF₃, CHCF₂, CH₂F, or CCl₃) having 1 to 10 carbon atoms substituted with a halogen atom, a hydroxy group, a nitro group, a cyano group, an amino group, an amidino group, a hydrazine, a hydrazone, a sulfonic acid group or a salt thereof, a phosphoric acid or a salt thereof, or an alkyl group having 1 to 10 carbon atoms, an alkenyl group having 2 to 10 carbon atoms, an alkynyl group having 2 to 10 carbon atoms, a cycloalkyl group having 3 to 20 carbon atoms, a heterocycloalkyl group having 3 to 20 carbon atoms, an aryl group having 6 to 20 carbon atoms, an arylalkyl group having 6 to 20 carbon atoms, a heteroaryl group having 6 to 20 carbon atoms, or a heteroarylalkyl group having 6 to 20 carbon atoms.

The alkyl group is a branched or unbranched (or straight-chain or linear) hydrocarbon group which is fully saturated. A non-limiting example of the alkyl groups may include methyl, ethyl, n-propyl, isopropyl, n-butyl, isobutyl, sec-butyl, n-pentyl, isopentyl, neopentyl, iso-amyl, n-hexyl, 3-methylhexyl, 2,2-dimethylpentyl, 2,3-dimethylpentyl, or n-heptyl. At least one hydrogen atom in the above alkyl group may be substituted with the substituent described above.

The alkenyl group refers to an aliphatic hydrocarbon containing at least one double bond. The alkynyl group refers to an aliphatic hydrocarbon containing at least one triple bond.

The cycloalkyl group refers to an aliphatic hydrocarbon containing at least one ring. In this case, the alkyl group has been described above.

The heterocycloalkyl group refers to a cycloalkyl group containing at least one heteroatom selected from N, O, P, or S. In this case, the cycloalkyl group has been described above.

The aryl group refers to an aromatic hydrocarbon used alone or in a combination form and including at least one ring. The aryl group includes a group in which an aromatic ring is fused to at least one cycloalkyl ring. A non-limiting example of the above aryl group includes a phenyl group, a naphthyl group, or a tetrahydronaphthyl group. At least one hydrogen atom of such an aryl group may be substituted with a substitutent, similarly to the alkyl group described above.

The arylalkyl group represents “alkyl group-aryl group-”, in which the alkyl group and the aryl group have been described above.

The heteroaryl group refers to a monocyclic or bicyclic organic compound containing at least one heteroatom selected from N, O, P or S, and having carbon as a reaming ring atom. The heteroaryl group may contain, for example, 1 to 5 heteroatoms and 5 to 10 ring members. The S or N may be oxidized to have various oxidation states. The monocyclic heteroaryl group may include, for example, a thienyl group, a furyl group, a pyrrolyl group, an imidazolyl group, a pyrazolyl group, a thiazolyl group, an isothiazolyl group, an 1,2,3-oxadiazolyl group, an 1,2,4-oxadiazolyl group, an 1,2,5-oxadiazolyl group, an 1,3,4-oxadiazolyl group, an 1,2,3-thiadiazolyl group, an 1,2,4-thiadiazolyl group, an 1,2,5-thiadiazolyl group, an 1,3,4-thiadiazolyl group, an isothiazol-3-yl group, an isothiazol-4-yl group, an isothiazol-5-yl group, an oxazol-2-yl group, an oxazol-4-yl group, an oxazol-5-yl group, an isoxazol-3-yl group, an isoxazol-4-yl group, an isoxazol-5-yl group, an 1,2,4-triazol-3-yl group, an 1,2,4-triazol-5-yl group, a 1,2,3-triazol-4-yl group, a 1,2,3-triazol-5-yl group, a tetrazolyl group, a pyrid-2-yl group, a pyrid-3-yl group, a 2-pyrazin-2-yl group, a pyrazin-4-yl group, a pyrazin-5-yl group, a 2-pyrimidin-2-yl group, a 4-pyrimidin-2-yl group, or a 5-pyrimidin-2-yl group. The heteroaryl group includes a heteroaromatic ring which is fused to at least one of aryl, cycloaliphatic, or heterocycle. The bicyclic heteroaryl group includes, for example, an indolyl group, an isoindolyl group, an indazolyl group, an indolizinyl group, a purinyl group, a quinolizinyl group, a quinolinyl group, or an isoquinolinyl group. At least one hydrogen atom of such heteroaryl group may be substituted with a substitutent, similarly to the alkyl group described above.

The heteroarylalkyl group represents “alkyl group-heteroaryl group-”, in which the aryl group has been described above. The heteroaryloxy group represents “heteroaryl group-O—”, in which the heteroaryl group has been described above.

The protective group may be attached to an acid-dissociative functional group and may be detached from a main chain in an acid-catalyst reaction. The protective group may be substituted or unsubstituted, and may be an alkyl group having 1 to 10 carbon atoms, a haloalkyl group having 1 to 10 carbon atoms, an aryl group having 6 to 18 carbon atoms, a haloaryl group, an arylalkyl group having 7 to 18 carbon atoms, an alkylaryl group having 7 to 18 carbon atoms, or a haloaryl group having 6 to 18 carbon atoms. According to one embodiment, the protective group may be an alkyl group in a linear-chain structure, a branched structure, or a cyclic structure having 1 to 6 carbon atoms, a vinyloxyethyl group, tetrahydropyranyl group, a tetrahydrofuranyl group, a trialkylsilyl group, isonobonyl, 2-methyl-2-adamantyl, 2-ethyl-2-adamantyl, 3-tetrahydrofuranyl, 3-oxoxyclohexyl, γ-butyllactone-3-yl, mavaloniclactone, γ-butyrolactone-2-yl, 3-methyl-γ-butyrolactone-3-yl, 2-tetrahydropyranyl, 2-tetrahydrofuranyl, 2,3-propylenecarbonate-1-yl, 1-methoxyethyl, 1-ethoxyethyl, 1-(2-methoxyethoxy)ethyl, 1-(2-acetoxyethoxy)ethyl, t-buthoxycarbonylmethyl, methoxymethyl, ethoxymethyl, trimethoxysilyl, triethoxysilyl, a methoxyethyl group, an ethoxyethyl group, an n-propoxyethyl group, an isopropoxyethyl group, an n-butoxyethyl group, an isobutoxyethyl group, a tert-butoxyethyl group, a cyclohexyloxyethyl group, a methoxypropyl group, an ethoxypropyl group, a 1-ethoxy-1-methyl-ethyl group, a tert-butoxycarbonyl (t-BOC), or tert-butoxycarbonyl methyl group. In addition, the alkyl group in the linear-chain structure or the branched structure may include a methyl group, an ethyl group, a propyl group, an isopropyl group, an n-butyl group, an isobutyl group, a tert-butyl group, a pentyl group, an isopentyl group, or a neopentyl group. Further, the alkyl group in the cyclic structure may include a cyclopentyl group, or a cyclohexyl group.

According to an embodiment of the present disclosure, the photosensitive polymer may have a molecular weight ranging from about 3,000 to about 500,000. According to an embodiment of the present disclosure, the photosensitive polymer may be included incontent ranging from about 0.1 wt % to about 5 wt %, ranging from about 0.2 wt % to about 3 wt %, or ranging from about 0.5 wt % to about 2.0 wt %, in the photoresist composition.

The photosensitive polymer in Chemical Formula 1 described above may be prepared using a reaction expressed as in Chemical Equation 2.

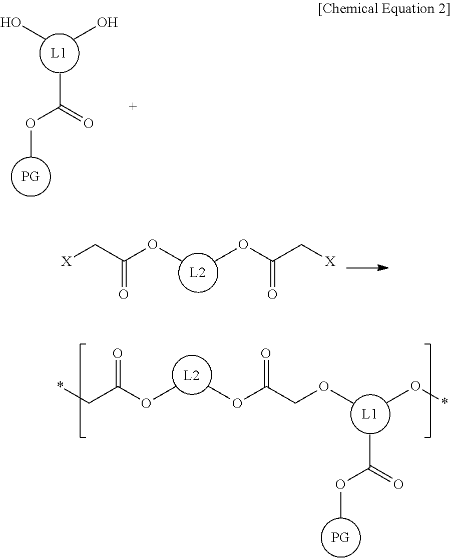

In this case, L1, L2, and PG of Chemical Equation 2 are identical to L1, L2, and PG of Chemical Equation 1. In addition, X may be a halogen atom, and may be, for example, any one of Cl, Br, or I.

As in Chemical Formula 1, the photosensitive polymer according to an embodiment of the present disclosure may be prepared through a polyether condensation reaction in which diol introduced with a protecting group is condensed with a haloester compound (e.g., chloroester).

In some embodiments, the photoacid generator is exposed to light to generate acid.

The photoacid generator may include a material having a structural Chemical Formula different from that of the photosensitive polymer. The photoacid generator may generate the acid when the photoacid generator is exposed by light having an ultraviolet wavelength band, especially, extreme ultraviolet (EUV) wavelength band. The light having the EUV wavelength band may be light selected from among a KrF excimer laser beam (248 nm), an ArF excimer laser beam (193 nm), an F2 excimer laser beam (157 nm), and an EUV laser beam (135 nm). The photoacid generator may include a material exposed to light to generate stronger acid having pKa (acid-dissociative constant) ranging from about −10 to about less than 1.

The photoacid generator may include, for example, triarylsulfonium salts, diaryliodonium salts, sulfonates or any combination thereof. The photoacid generator may include at least one of triphenylsulfonium triflate, triphenylsulfonium antimonate, triphenylsulfonium difluoroalkyl sulfonate, diphenyliodonium triflate, diphenyliodonium antimonate, methoxydiphenyliodonium triflate, di-t-butyldiphenyliodonium triflate, 2,6-dinitrobenzyl sulfonates, pyrogallol tris(alkylsulfonates), N-hydroxysuccinimide triflate, norbornene-dicarboximide-triflate, triphenylsulfonium nonaflate, diphenyliodonium nonaflate, methoxydiphenyliodonium nonaflate, di-t-butyldiphenyliodonium nonaflate, N-hydroxysuccinimide nonaflate, norbornene-dicarboximide-nonaflate, triphenylsulfonium perfluorobutanesulfonate, triphenylsulfonium perfluorooctanesulfonate (PFOS), diphenyliodonium PFOS, methoxydiphenyliodonium PFOS, di-t-butyldiphenyliodonium triflate, N-hydroxysuccinimide PFOS, norbornene-dicarboximide PFOS or any combination thereof.

According to an embodiment of the present disclosure, in the photoresist composition, the photoacid generator may be included in content ranging from about 0.01 wt % to about 40.0 wt %, ranging from about 0.05 wt % to about 35 wt %, or ranging from about 0.1 wt % to about 30 wt %, based on the total weight of the photosensitive polymer.

The solvent included in the photoresist composition may include an organic solvent. The organic solvent may include at least one of ether, alcohol, glycol ether, an aromatic hydrocarbon compound, ketone, or ester, but the present disclosure is not limited thereto. For example, the organic solvent may include ethylene glycol monomethyl ether, ethylene glycol monoethyl ether, methylcellosolve acetate, ethylcellosolve acetate, diethylene glycol methyl ether, diethylene glycol ethyl ether, propylene glycol, propylene glycol methyl ether (PGME), propylene glycol methyl ether acetate (PGMEA), propylene glycol ethyl ether, propylene glycol ethyl ether acetate, propylene glycol propyl ether acetate, propylene glycol butyl ether, propylene glycol butyl ether acetate, ethanol, propanol, isopropyl alcohol, isobutyl alcohol, 4-methyl-2-pentanol (methyl isobutyl carbion: MIBC), hexanol, 1-methoxy-2-propanol, 1-ethoxy-2-propanol, ethylene glycol, propylene glycol, heptanone, propylene carbonate, butylene carbonate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, gamma-butyrolactone, methyl 2-hydroxyisobutyrate, methoxybenzene, n-butyl acetate, 1-methoxy-2-propyl acetate, methoxyethoxy propionate, ethoxyethoxy propionate, or any combination thereof. The organic solvent may be used individually or in the form of a combination of at least two types of the above materials.

According to an embodiment of the present disclosure, the photoresist composition may contain the solvent provided in a remaining content except for the content of main components such as the photosensitive polymer and the photoacid generator. When the photosensitive composition includes different components (e.g., a base quencher to be described below, or a surfactant), the photoresist composition may include the solvent provided in the remaining content except for the content of main components and the content of the different components. According to some embodiments, the solvent may be included in content ranging from about 80 wt % to about 99.9 wt %, ranging from about 90 wt % to about 99.9 wt %, or ranging from about 95 wt % to about 99.9 wt %, based on the total weight of the photoresist composition.

According to an embodiment of the present disclosure, the photoresist composition may further include a base quencher.

The base quencher may trap acid in the non-exposed area when the acid generated from the photoacid generator is diffused into the non-exposed area of the photoresist layer included in the photoresist composition. According to an embodiment of the present disclosure, the base quencher is included in the photoresist composition to prevent the acid, which is generated from the exposed area of the photoresist layer, from being diffused into the non-exposed area of the photoresist layer, after the photoresist layer obtained from the photoresist composition is exposed.

According to some embodiments, the base quencher may include primary aliphatic amine, secondary aliphatic amine, tertiary aliphatic amine, aromatic amine, heterocyclic ring-containing amine, a nitrogen-containing compound having a carboxyl group, a nitrogen-containing compound having a sulfonyl group, a nitrogen-containing compound having a hydroxyl group, a nitrogen-containing compound having a hydroxyphenyl group, an alcoholicnitrogen-containing compound, amides, imides, carbamates, or ammonium salts. For example, the base quencher may include triethanol amine, triethyl amine, tributyl amine, tripropyl amine, hexamethyl disilazan, aniline, N-methylaniline, N-ethylaniline, N-propylaniline, N,N-dimethylaniline, N,N-bis(hydroxyethyl) aniline, 2-methylaniline, 3-methylaniline, 4-methylaniline, ethylaniline, propylaniline, dimethylaniline, 2,6-diisopropylaniline, trimethylaniline, 2-nitroaniline, 3-nitroaniline, 4-nitroaniline, 2,4-dinitroaniline, 2,6-dinitroaniline, 3,5-dinitroaniline, N,N-dimethyltoluidine, or any combination thereof, but the present disclosure is not limited thereto.

According to some embodiments, the base quencher may include a photo-labile base. The photo-labile base may include a compound exposed by light to generate acid, or to neutralize acid before being exposed by light. When the photo-labile base is exposed by light to be dissociated, the photo-labile base may not trap the acid. Accordingly, when a partial area of the photoresist layer formed based on a chemical-amplification resist composition including the base quencher including the photo-labile base is exposed by light, the photo-labile base loses alkalinity in the exposed area of the photoresist layer, and traps acid in the non-exposed area of the photoresist layer, thereby preventing the acid, which is generated in the exposed area of the photoresist layer, from being diffused to the non-exposed area of the photoresist layer.

The photo-labile base may include a carboxylate salt or a sulfonate salt of a photo-labile cation. For example, the photo-labile cation may form a complex with an anion of a carboxylic acid having 1 to 20 carbon atoms. The carboxylic acid may be, for example, formic acid, acetic acid, propionic acid, tartaric acid, succinic acid, cyclohexylcarboxylic acid, benzoic acid, or salicylic acid, but the present disclosure is not limited thereto.

According to an embodiment of the present disclosure, the photoresist composition may include the base quencher in the content ranging from about 0.01 wt % to about 20 wt %, or any range therein, but the present disclosure is not limited thereto.

According to some embodiments, the photoresist composition according to an embodiment of the present disclosure may further include at least one selected from a surfactant, a dispersant, an absorbent, and a coupling agent.

The surfactant may improve coating uniformity of the photoresist composition, and improve the wettability. According to some embodiments, the surfactant may include a sulfuric acid ester salt, a sulfonate salt, phosphoric acid ester, a soap, an amine salt, a quaternary ammonium salt, a polyethylene glycol, an alkylphenol ethylene oxide adduct, a polyhydric alcohol, a nitrogen-containing vinyl polymer, or any combination thereof, but the present disclosure is not limited thereto. For example, the surfactant may be selected from among a fluoroalkyl benzene sulfonate, a fluoroalkyl carboxylate, fluoroalkyl polyoxyethylene ether, fluoroalkyl ammonium iodide, fluoroalkyl betaine, a fluoroalkyl sulfonate, diglycerin tetrakis (fluoroalkyl polyoxyethylene ether), a fluoroalkyl trimethyl ammonium salt, a fluoroalkyl amino sulfonate, polyoxyethylene nonyl phenyl ether, polyoxyethylene octyl phenyl ether, polyoxyethylene alkyl ether, polyoxyethylene lauryl ether, polyoxyethylene oleyl ether, polyoxyethylene tridecyl ether, polyoxyethylene cetyl ether, polyoxyethylene stearyl ether, polyoxyethylene laurate, polyoxyethylene oleate, polyoxyethylene stearate, polyoxyethylene lauryl amine, sorbitan laurate, sorbitan palmitate, sorbitan stearate, sorbitan oleate, sorbitan fatty acid ester, polyoxyethylene sorbitan laurate, polyoxyethylene sorbitan palmitate, polyoxyethylene sorbitan stearate, polyoxyethylene sorbitan oleate, polyoxyethylene naphthyl ether, alkyl benzene sulfonate, and alkyl diphenyl ether disulfonate, but the present disclosure is not limited thereto. The surfactant may be included in content ranging about 0.001 wt % to about 0.1 wt %, based on the total weight of the photosensitive polymer, or any range therein, but the present disclosure is not limited thereto.

The dispersant may allow components constituting the photoresist composition to be uniformly dispersed in the photoresist composition. According to some embodiments, the dispersant may include epoxy resin, polyvinyl alcohol, polyvinyl butyral, polyvinyl pyrrolidone, glucose, sodium dodecyl sulfate, sodium citrate, oleic acid, linoleic acid, or any combination thereof, but the present disclosure is not limited thereto. When the photoresist composition includes the dispersant, the dispersant may be included in the content ranging from about 0.001 wt % to about 5 wt %, or any range therein, based on the total weight of the photoresist composition.

The absorbent may prevent an adverse influence by moisture included in the photoresist composition. For example, the absorbent may prevent metal, which is included in the photoresist composition, from being oxidized by the moisture. According to some embodiments, the absorbent may include polyoxyethylene nonylphenol ether, polyethylene glycol, polypropylene glycol, polyacrylamide, or any combination thereof, but the present disclosure is not limited thereto. When the photoresist composition includes the absorbent, the absorbent may be included in the content ranging from about 0.001 wt % to about 10 wt %, or any range therein, based on the total weight of the photoresist composition.

The coupling agent may improve the adhesion to the underlayer when the photoresist composition is coated onto the underlayer. According to some embodiments, the coupling agent may include a silane coupling agent. The silane coupling agent may include vinyltrimethoxysilane, vinyltriethoxysilane, vinyltrichlorosilane, vinyltris(β-methoxyethoxy)silane, 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyldiethoxysilane, or trimethoxy[3-(phenylamino)propyl]silane. When the photoresist composition includes the coupling agent, the coupling agent may be included in the content ranging from about 0.001 wt % to about 5 wt %, or any range therein, based on the total weight of the photoresist composition.

According to an embodiment of the present disclosure, the photoresist composition may further include water, when the solvent includes only an organic solvent in the photoresist composition. In this case, the photoresist composition may include water included in the content ranging from about 0.001 wt % to about 0.1 wt %, or any range therein.

In the photolithography process of employing the photoresist composition according to an embodiment of the present disclosure described above, when a partial area of the photoresist layer resulting from the photoresist composition is exposed to the light, the main chain and the protecting group are cleaved by acid generated through the exposure and decomposed to molecules having a carboxyl group (—COOH), such that the solubility for the developer is increased.

For example, the photosensitive polymer of Chemical Formula 1 may be decomposed through the reaction expressed as in Chemical Equation 3 in the exposure process.

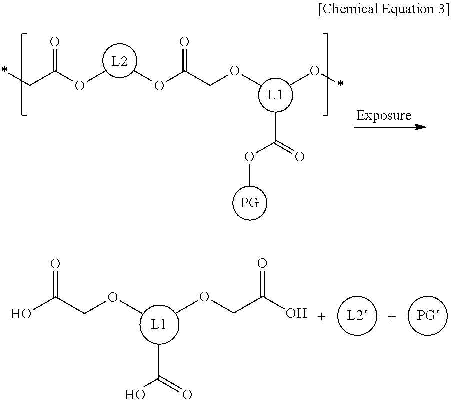

In this case, L2′ is a product reduced from L2, as L2 is cleaved from the bond to two ester groups, and PG′ is a product reduced from PG, as PG is cleaved from the bond to an ester group.

The photosensitive polymer according to the present disclosure may be decomposed into mutually different three molecules such as a tricarboxylic acid compound, a compound reduced from L1, and a compound reduced from PG as in Chemical Formula 3.

Chemical Formula 3 shows groups corresponding to Chemical Equation 1. Chemical Formula 3 shows two repeating units, which are adjacent to each other, together, for the convenience of explanation.

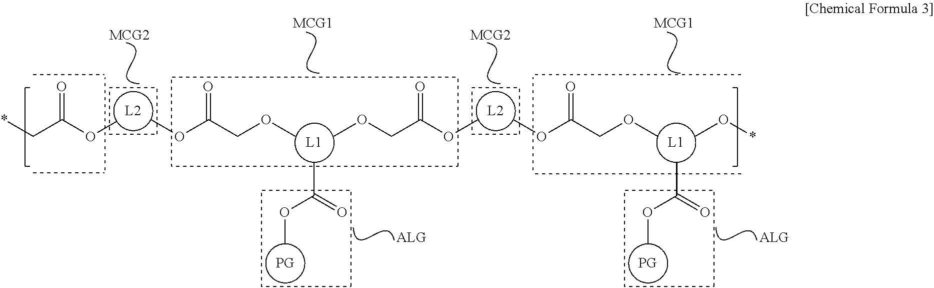

Referring to Chemical Equation 1, Chemical Formula 2, and Chemical Formula 3, the first main chain group may have an ester group, which serves as acid-dissociative functional group, at a portion bonded to the second main chain group, and may have an ester group, which serves as an acid-dissociative functional group, at a bonding portion between the first main chain group and the acid-dissociative group. In some embodiments, the photosensitive polymer is decomposed, as a cleavage occurs at a position having the acid-dissociative functional group (that is, the ester group) by employing, as a catalyst, acid generated from the photoacid generator in the exposure process. In other words, the photosensitive polymer is decomposed, as cleavage occurs inside a main chain (e.g., between the first main chain group and the second main chain group) and at a bonded portion between the main chain and the protecting group (e.g., between the first main chain group and the protecting group).

In some embodiments, the decomposition product has a significantly smaller molecular weight than the molecular weight of the photosensitive polymer in the photoresist in an initial stage. In addition, the decomposition product has a different polarity from the photosensitive polymer in an initial stage. In addition, in some embodiments, the first main chain group in the decomposition product may have a plurality of carboxylic acid groups as terminal groups. The first main chain group may be increased in the solubility for a developer due to the carboxylic acid terminal groups having a higher hydrophilic property and a higher polarity. In some embodiments, the photosensitive polymer has a molecular weight reduced as the main chain is decomposed to improve the solubility for the developer.

As described above, the photoresist composition according to an embodiment of the present disclosure has a polarity (especially, the hydrophilic or hydrophobic property) and the size of a molecule weight varied depending on whether cleavage occurs between the main chain and the protecting group in the exposed area and the non-exposed area. Accordingly, the solubility for the developer may be significantly increased in the exposed area.

Accordingly, when the photolithography process is employed to fabricate an integrated circuit device using the photoresist composition according to embodiments of the present disclosure, the solubility contrast for the developer is sufficiently ensured between the exposed area and the non-exposed area of the photoresist layer, thereby improving the resolution. According to an embodiment of the present disclosure, as the solubility contrast for the developer may be maximized between the exposed area and the non-exposed area, thereby improving line edge roughness (LER) and line width roughness (LWR). As the solubility contrast for the developer is maximized between the exposed area and the non-exposed area, higher pattern fidelity may be achieved.

When the integrated circuit device is fabricated in the photolithography process by employing the photoresist composition having higher solubility contrast for the developer, the precision of the pattern dimension necessary for the integrated circuit device may be improved, and the productivity in the fabricating process of the integrated circuit device may be improved.

According to an embodiment of the present disclosure, the photosensitive polymer may be a polymer having a repeating unit shown in Chemical Formula 4.

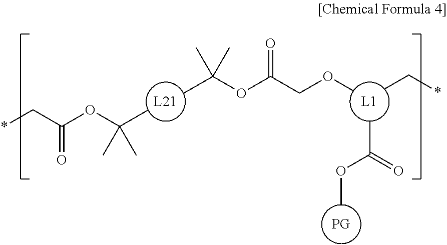

In this case, L1 of Chemical Formula 4 is identical to L1 of Chemical Formula 1, and PG of Chemical Formula 4 is identical to PG of Chemical Formula 1. In addition, L21 of Chemical Formula 4 is identical to L2 of Chemical Formula 1.

The photosensitive polymer in Chemical Formula 4 may be prepared using a reaction expressed as in Chemical Equation 4.

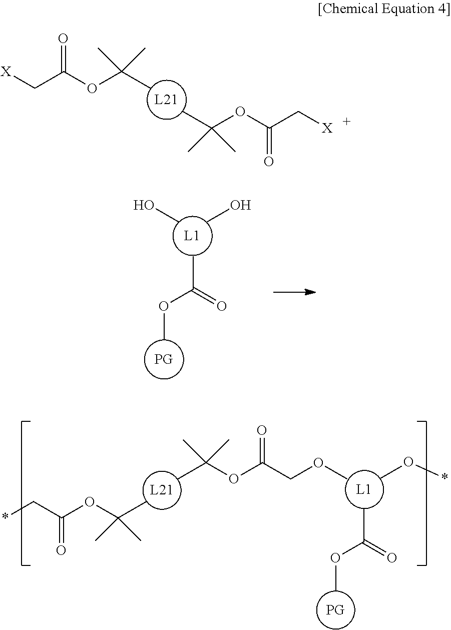

In this case, L1 of Chemical Equation 4 is identical to L1 of Chemical Formula 1, and P′ of Chemical Equation 4 is identical to PG of Chemical Formula 1. In addition, L21 of Chemical Equation 4 is identical to L2 of Chemical Formula 1, X may be a halogen atom, and has been described above.

In some embodiments, the photosensitive polymer of Chemical Equation 4 may be decomposed through the reaction expressed as in Chemical Equation 5 in the exposure process.

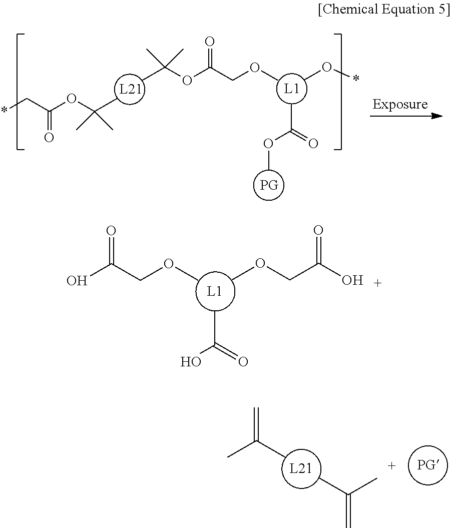

In this case, L1 of Chemical Equation 5 is identical to L1 of Chemical Formula 1, and PG of Chemical Equation 5 is identical to PG of Chemical Formula 1. In addition, L21 of Chemical Equation 5 is identical to L2 of Chemical Formula 1, PG′ is a product reduced as cleavage occurs in the bond to an adjacent carboxylate ester group.

The photosensitive polymer of Chemical Formula 4 may be a photosensitive polymer expressed as in Chemical Formula 5.

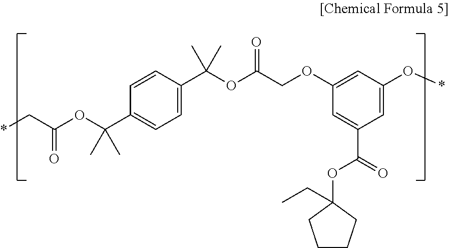

According to an embodiment of the present disclosure, the protecting group may be provided in various forms. Chemical Formula 6 shows a photosensitive polymer having a different protecting group.

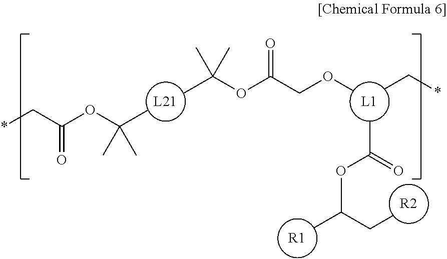

In this case, L1 of Chemical Formula 6 is identical to L1 of Chemical Formula 1. In addition, L21 of Chemical Formula 6 is identical to ‘L2’ of Chemical Formula 1,

In Chemical Formula 6, each of ‘R1’ and ‘R2’ may be independently an alkyl group in a linear-chain structure, a branched structure, or a cyclic structure having 1 to 6 carbon atoms, a vinyloxyethyl group, tetrahydropyranyl group, a tetrafuranyl group, a trialkylsilyl group, isonobonyl, 2-methyl-2-adamantyl, 2-ethyl-2-adamantyl, 3-tetrahydrofuranyl, 3-oxoxyclohexyl, γ-butyllactone-3-yl, mavaloniclactone, γ-butyrolactone-2-yl, 3-methyl-γ-butyrolactone-3-yl, 2-tetrahydropyranyl, 2-tetrahydrofuranyl, 2,3-propylenecarbonate-1-yl, 1-methoxyethyl, 1-ethoxyethyl, 1-(2-methoxyethoxy)ethyl, 1-(2-acetoxyethoxy)ethyl, t-buthoxycarbonylmethyl, methoxymethyl, ethoxymethyl, trimethoxysilyl, triethoxysilyl, a methoxyethyl group, an ethoxyethyl group, an n-propoxyethyl group, an isopropoxyethyl group, an n-butoxyethyl group, an isobutoxyethyl group, a tert-butoxyethyl group, a cyclohexyloxyethyl group, a methoxypropyl group, an ethoxypropyl group, a 1-ethoxy-1-methyl-ethyl group, a 1-ethoxy-1-methylethyl group, a tert-butoxycarbonyl (t-BOC), or tert-butoxycarbonyl methyl group. In addition, the alkyl group in the linear-chain structure or the branched structure may include a methyl group, an ethyl group, a propyl group, an isopropyl group, an n-butyl group, an isobutyl group, a tert-butyl group, a pentyl group, an isopentyl group, or a neopentyl group. Further, the alkyl group in the cyclic structure may include a cyclopentyl group, or a cyclohexyl group.

For example, the photosensitive polymer of Chemical Formula 6 may be decomposed through the reaction expressed as in Chemical Equation 6 in the exposure step.

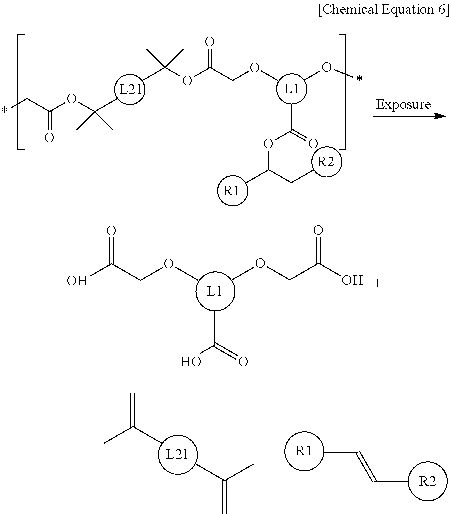

In this case, L1, L21, R1, and R2 of Chemical Equation 6 are identical to L1, L21, R1, and R2 of Chemical Formula 6.

The photoresist composition according to the present disclosure described above may be employed when fabricating the semiconductor device, for example, the integrated circuit device.

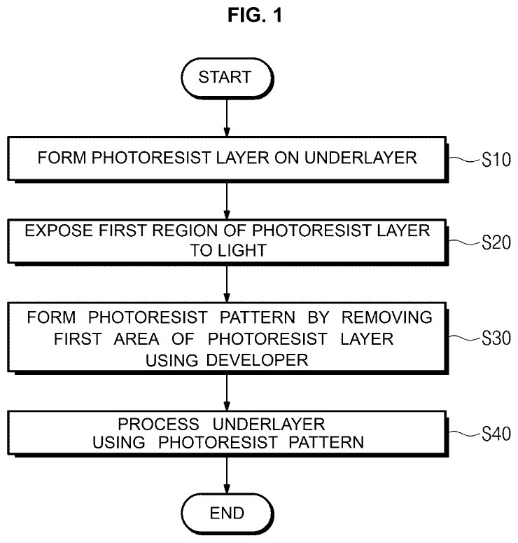

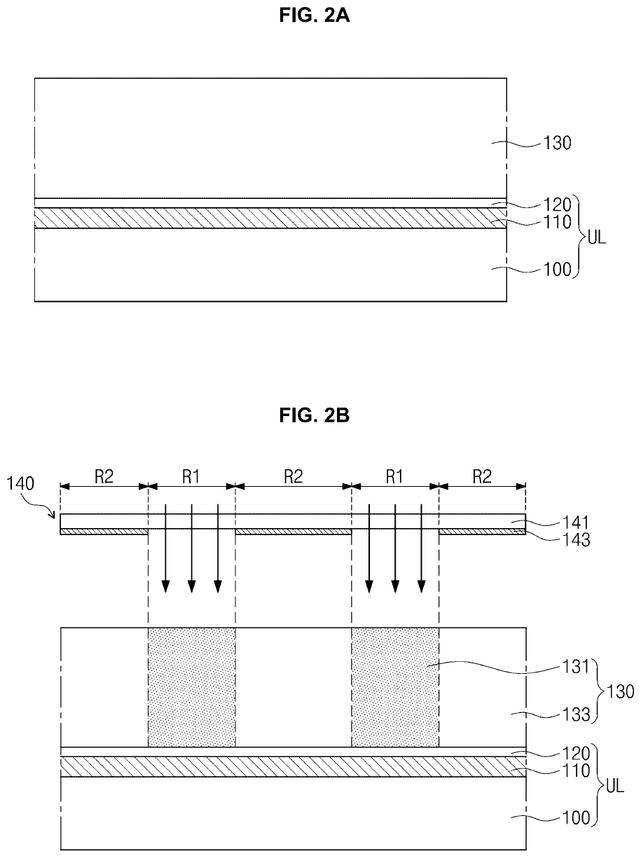

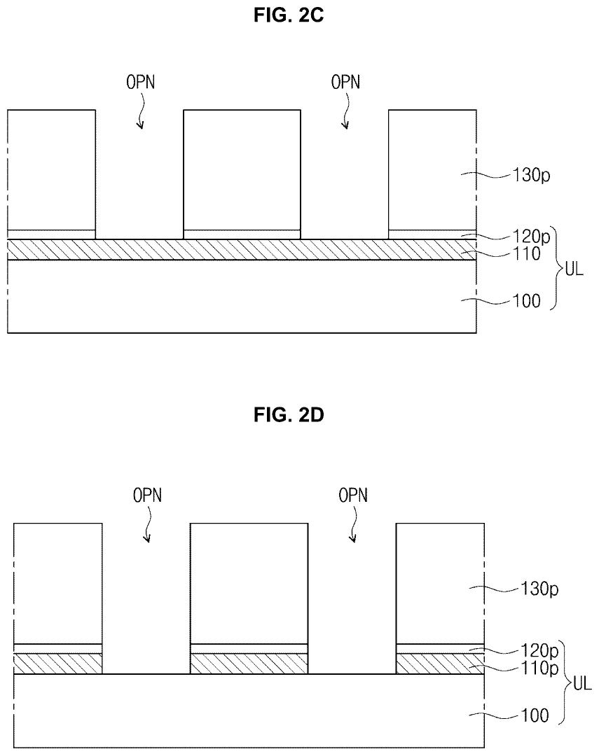

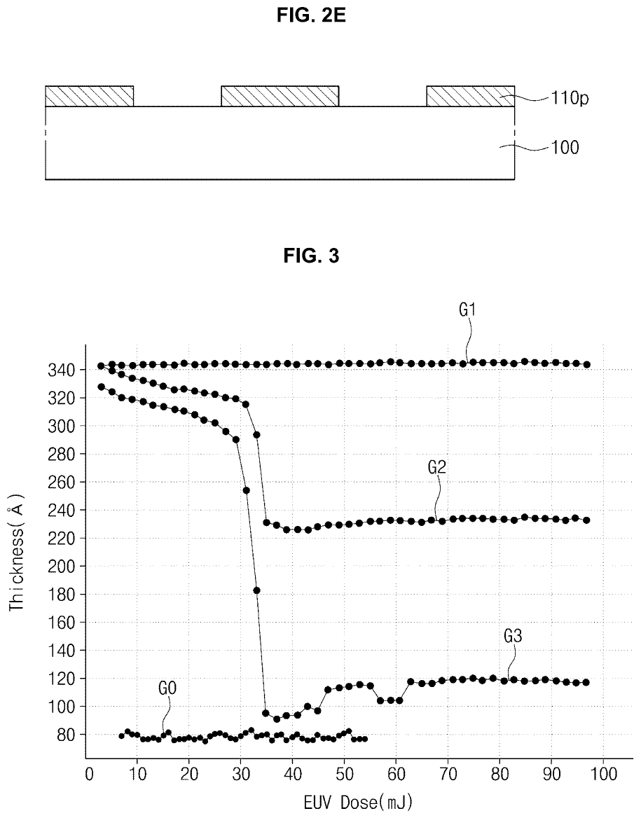

FIG. 1 is a flowchart illustrating a method for fabricating an integrated circuit device according to an embodiment of the present disclosure. FIGS. 2A to 2E are cross-sectional views illustrating a method for fabricating an integrated circuit device in a process sequence according to an embodiment of the present disclosure.

According to an embodiment of the present disclosure, the integrated circuit device may be fabricated by forming a photoresist layer on an underlayer (S10), exposing a specific area, for example a first area, of the photoresist layer to light (S20), forming a photoresist pattern by removing an exposed area (that is, a first area) of the photoresist layer by using a developer (S30), and processing the underlayer by employing the photoresist pattern as a mask (S40). The details thereof are as follows.

Referring to FIGS. 1 and 2A, a photoresist layer 130 may be formed on an underlayer UL.

The underlayer UL may include a substrate 100 and a feature layer 110 formed on the substrate 100. The feature layer 110 may be a target layer to form a specific pattern in a final stage.

The substrate 100 may include a semiconductor substrate. For example, the substrate 100 may include a semiconductor material, such as Si or Ge, or a compound semiconductor material, such as SiGe, SiC, GaAs, InAs, or InP. However, the material of the substrate 100 is not limited thereto. For example, the substrate 100 may include various materials, as long as the substrate 100 serves as a base of the feature layer 110. For example, the substrate 100 may include various materials, such as metal, glass, or a polymer resin.

The feature layer 110 may be an insulating layer, a conductive layer, or a semiconductor layer. For example, the feature layer 110 may include metal, an alloy, a metal carbide, a metal nitride, a metal oxynitride, a metal oxycarbide, a semiconductor, polysilicon, an oxide, a nitride, an oxynitride, or any combination thereof, but the present disclosure is not limited thereto.

According to some embodiments, as illustrated in FIG. 2A, the underlayer UL may include a developed bottom anti-reflective coating (DBARC) layer 120 formed on the feature layer 110. In this case, the photoresist layer 130 may be formed on the DBARC layer 120.

The DBARC layer 120 may control scattered-reflection of light from a light source used in the exposure process to fabricate the integrated circuit device, or may absorb light reflected from the feature layer 110 under the DBARC layer 120. According to some embodiments, the DBARC layer 120 may include an organic anti-reflective coating (ARC) material for a KrF excimer laser, an ArF excimer laser, or a different arbitrary light source. According to some embodiment, the DBARC layer 120 may include an organic ingredient having a light absorbing structure. The light absorbing structure may be a hydrocarbon compound having, for example, at least one benzene ring, or a structure in which benzene rings are fused. The DBARC layer 120 may be formed to have the thickness of about 20 nm to about 100 nm or any range therein, but the present disclosure is not limited thereto. According to some embodiments, the DBARC layer 120 may be omitted.

The photoresist layer 130 formed on the underlayer UL may be formed using the photoresist composition including the photosensitive polymer described above. According to some embodiments, the photoresist composition may include the photosensitive polymer including a first repeating unit expressed as in Chemical Equation 1, the photoacid generator, and the solvent.

According to some embodiments, the photoresist composition may further include a base quencher.

According to some embodiments, the photoresist composition may further include different ingredients such as a surfactant.

The details of the photosensitive polymer and the photoresist composition have been described above.

The photoresist composition may be coated onto the DBARC layer 120 to form the photoresist layer 130. The coating may be performed through spin coating, spray coating, dip coating, or aerosol coating. The coated photoresist composition may be heat-treated to remove the solvent from the photoresist layer. The temperature for the heat treatment may be lower than the temperature for the pyrolysis of components of the photoresist composition. For example, the photoresist composition may undergo the heat treatment process at a temperature ranging from about 80° C. to about 300° C., or any temperature range therein, for the time ranging from about 10 seconds to about 100 seconds, or any time range therein. However, the temperature for the heat treatment process for the photoresist composition is not limited thereto. The photoresist layer 130 may have the thickness which is several tens to several hundreds of times the thickness of the DBARC layer 120. The photoresist layer 130 may have a thickness ranging from about 5 nm to about 300 nm, ranging from about 10 nm to about 200 nm, or ranging from about 20 nm to about 100 nm, but the present disclosure is not limited thereto.

Referring to FIGS. 1 and 2B, the area of the photoresist layer 130 is divided based on the pattern of the feature layer 110 to be formed thereafter in the final stage and the exposure type (that is, a positive type or a negative type) of the photoresist layer 130, and a partial area of the photoresist layer 130 among the divided areas is exposed to light. According to the present embodiment, the exposed area is expressed as a first area 131 and a non-exposed area is expressed as a second area 133.

When the first area 131, which is a portion of the photoresist layer 130, is exposed to light, photoacid is generated from the photoacid generator in the first area 131 of the photoresist layer 130, and the photosensitive polymer is decomposed in the photoresist layer 130 by employing the photoacid as a catalyst. In the photosensitive polymer, as cleavage occurs between the main chain and the protecting group, the change in polarity and molecular weight of the reaction product is induced as described above.

According to some embodiments, to expose the first area 131 of the photoresist layer 130 to the light, a photomask 140 having a plurality of light shielding areas and a plurality of light transmitting areas may be aligned at a specific position on the photoresist layer 130. In this case, the plurality of transmitting areas may be aligned to be positioned corresponding to the first area 131 of the photoresist layer 130. Then, the first area 131 of the photoresist layer 130 may be exposed to light through the plurality of transmitting areas of the photomask 140. To expose the first area 131 of the photoresist layer 130, a KrF excimer laser beam (248 nm), an ArF excimer laser beam (193 nm), an F2 excimer laser beam (157 nm), or an EUV laser beam (135 nm) may be used.

The photomask 140 may include a transparent substrate 141 and a plurality of light shielding patterns 143 formed in a plurality of light shielding areas on the transparent substrate 141. In some embodiments, the transparent substrate 141 may include quartz. The plurality of light shielding patterns 143 may include chromium (Cr), but the present disclosure is not limited thereto. A plurality of transmission areas R1 and a plurality of non-transmission areas R2 may be defined by the plurality of light shielding patterns 143. The transmission area R1 has no light shielding area 143, and the non-transmission area R2 has the light shielding pattern 143.

According to some embodiments, an annealing process may be performed to diffuse multiple acids in the first area 131 of the photoresist layer 130. For example, the annealing process is performed with respect to a result structure, which is obtained after the first area 131 of the photoresist layer 130 is exposed to light, at a temperature ranging from about 20° C. to about 250° C., for example, ranging from about 23° C. to about 200° C. to diffuse at least a portion of the multiple acids into the first area 131, thereby more uniformly distributing the multiple acids in the first area 131. The annealing process may be performed for about 0 second to about 200 seconds, or any time range therein. For example, the annealing process may be performed at the temperature of about 100° C. for about 60 seconds.

According to other embodiments, an annealing process may not be performed to diffuse multiple acids in the first area 131 of the photoresist layer 130. In this case, the multiple acids may be diffused into the first area 131 of the photoresist layer 130 without the annealing process while the first area 131 of the photoresist layer is exposed to the light.

As the multiple acids may be diffused into the first area 131 of the photoresist layer 130, the photosensitive polymer constituting the photoresist layer 130 in the first area 131 may be decomposed as described above. Accordingly, as the photosensitive polymer decomposed is increased in polarity and decreased in molecular weight, the first area 131 of the photoresist layer 130 may be changed to be in a state easily dissolved in an alkaline developer.

The intensity of energy of light irradiated to the first area 131, which is the exposed area of the photoresist layer 130, follows the Gaussian distribution. Accordingly, the higher energy density is shown at the central portion of a beam spot to which light is irradiated, and the lower energy density is shown toward the peripheral portion of the beam spot. An edge portion, which is adjacent to the first area 131, of the second area 133, which is the non-exposed area of the photoresist layer 130, may receive the light corresponding to the peripheral portion, which has the lower energy density, of the beam spot. However, when light having the higher energy density is irradiated to the edge portion, which is adjacent to the first area 131, of the second area 133, which is the non-exposed area of the photoresist layer 130, acid may be excessively generated to excessively amplify the decomposition reaction by acid. When the decomposition reaction by acid is excessively amplified, the pattern to be formed may not be formed, so the resolution of the pattern may be degraded.

However, since the photosensitive polymer according to an embodiment of the present disclosure has solubility for the developer, which is increased even when light having a lower energy density is irradiated, the solubility contrast for the developer may be maximized between the first area 131 and the second area 133 which are the exposed area and the non-exposed area in the photoresist layer 130, respectively.

In addition, when the base quencher is contained in the photoresist layer 130, the base quencher, which is contained in the photoresist layer 130, may act as a quenching base for neutralizing acids, which are unintentionally diffused from the first area 131 to the second area 133, in the second area 133 (the non-exposed area). Accordingly, the solubility contrast for the developer may be maximized between the first area 131, which is the exposed area, and the second area 133, which is the non-exposed area, in the photoresist layer 130.

Referring to FIGS. 1 and 2C, the photoresist layer 130 may be developed using the developer to remove the first area 131 of the photoresist layer 130. Accordingly, a photoresist pattern 130P including only the second area 133, which is the non-exposed area, of the photoresist layer 130 may be formed.

The photoresist pattern 130P may include a plurality of openings OPN. After forming the photoresist pattern 130P, portions, which are exposed through the plurality of openings OPN, of the DBARC layer 120 may be removed to form a DBARC pattern 120P.

According to some embodiments, an alkaline developer may be used to develop the photoresist layer 130. The alkaline developer may include, for example, 2.38 wt % of tetramethylammonium hydroxide (TMAH) solution. In addition to TMAH, the developer may include various organic solvents and may further include an additive such as a surfactant.

Accordingly, since the polarity (e.g., hydrophilicity) of the photosensitive polymer is increased in the first area 131 of the photoresist layer 130, the solubility of the first area 131 for the developer may be improved while the photoresist layer 130 is developed by using the developer, such that the first area 131 is clearly removed. Accordingly, a vertical sidewall profile may be obtained in the photoresist pattern 130P. As described above, as the profile of the photoresist pattern 130P is enhanced, when the feature layer 110 is processed by using the photoresist pattern 130P, a critical dimension may be precisely controlled in an intended area to be processed in the feature layer 110.

Referring to FIGS. 1 and 2D, the underlayer UL may be processed using the photoresist pattern 130P.

To process the underlayer UL, various processes may be performed. The various processes may include etching the feature layer 110 exposed through the opening OPN of the photoresist pattern 130P, implanting impurity ions into the feature layer 110, forming an additional layer on the feature layer 110 through the opening OPN, and deforming a portion of the feature layer 110 through the opening OPN. FIG. 2D illustrates a process of processing the underlayer UL, in which the feature layer 110 exposed through the opening OPN is etched to form a feature pattern 110P.

Referring to FIG. 2E, the photoresist pattern 130P and the DBARC pattern 120P remaining on the feature pattern 110P may be removed from the result structure of FIG. 2D. To remove the photoresist pattern 130P and the DBARC pattern 120P, ashing and strip processes may be used.

According to various embodiments, the process for forming the feature layer 110 may be omitted, which is different from the above-description. In this case, the substrate 100 may be processed through the photoresist pattern 130P. For example, various processes may be performed, and the various processes may include etching of a portion of the substrate 100 by using the photoresist pattern 130P, implanting impurity ions into a partial area of the substrate 100, forming an additional layer on the substrate 100 through the opening OPN, and modifying a portion of the substrate 100 through the opening OPN.

In the method for fabricating the integrated circuit device according to the technical spirit of the present disclosure described with reference to FIGS. 1, 2A, and 2E, the difference in solubility for the developer between the exposed area and the non-exposed area of the photoresist layer obtained may be increased using the photoresist composition according to the technical spirit of the present disclosure. Accordingly, the LER and the LWR may be reduced in the photoresist pattern obtained from the photoresist layer to provide higher pattern fidelity. Accordingly, when the subsequent process is performed with respect to the feature layer and/or the substrate using the photoresist pattern 130P, the critical dimension of processing areas or patterns to be formed on the feature layer and/or the substrate may be precisely controlled to improve the dimension precision. In addition, the distribution of critical dimension (CD) of the patterns to be realized on the substrate may be uniformly controlled, and the productivity of the process for fabricating the integrated circuit device may be improved.

FIG. 3 is a graph illustrating the thickness of a remaining portion after development for the exposed area, as the function of an exposed dose, when the photoresist layer is formed on the underlayer using the photoresist composition according to an embodiment of the present disclosure. Tetramethylammonium hydroxide (TMAH) was used as a developer.

In FIG. 3, G0 represents the thickness of the underlayer UL when the photoresist layer is not formed, G1 represents the thickness of the photoresist layer when the exposure and development processes is not performed, G2 represents the thickness of the photoresist layer when the exposure process is performed, and G3 represents the thickness of the photoresist layer when both the exposure and development processes are performed.

Referring to FIG. 3, when the photoresist composition according to the present disclosure was used, and when light of less than a critical exposure dose (within about 34 mJ in FIG. 3) was irradiated, the thickness of the photoresist layer was maintained without the great difference from the thickness of the photoresist layer in the initial coating step. However, when light was irradiated with at least the critical exposure dose, even though only the exposure process was performed, the thickness of the photoresist layer was significantly reduced. When both the exposure process and the development process were performed, almost the entire portion of the photoresist layer was removed. In addition, even though the thickness of the photoresist layer in the initial coating was maintained before the exposure process and the development process, almost the entire portion of the photoresist layer was removed after the exposure and development process. Accordingly, the thickness of the photoresist layer remaining is significantly reduced.

Accordingly, when the exposure and development processes are performed with respect to the specific area of the photoresist layer, almost the entire portion of the photoresist layer may be removed. Accordingly, the contrast of the profile may be improved in the photoresist pattern. As described above, as the profile of the photoresist pattern is improved, when the feature layer is processed by using the photoresist pattern, a critical dimension may be precisely controlled in an intended area to be processed in the feature layer.

An embodiment of the present disclosure may provide a photoresist composition to improve solubility contrast for a developer between an exposed area and a non-exposed area in a photoresist layer in a photolithography process.

An embodiment of the present disclosure may provide a method for fabricating a semiconductor device, capable of improving the precision of a pattern dimension by improving solubility contrast for a developer between an exposed area and a non-exposed area of a photoresist layer in a photolithography process.

Although an embodiment of the present disclosure has been described for illustrative purposes, those skilled in the art will appreciate that various modifications, and substitutions are possible, without departing from the scope and spirit of the present disclosure as disclosed in the accompanying claims.

Accordingly, the technical scope of the present disclosure is not limited to the detailed description of this specification, and may be defined by the claims.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A photoresist composition comprising:
a photosensitive polymer, a photoacid generator, and a solvent,
wherein the photosensitive polymer includes:
a first main chain group, a second main chain group, and an acid-dissociative group attached to the first main chain group, and
wherein at least one of the first main chain group or the second main chain group comprises an acid-dissociative functional group which is cleaved between the first main chain group and the second main chain group and between the first main chain group and the acid-dissociative group under presence of an acid catalyst.

2. The photoresist composition of claim 1, wherein the photosensitive polymer comprises:
a repeating unit of Chemical Formula 1, 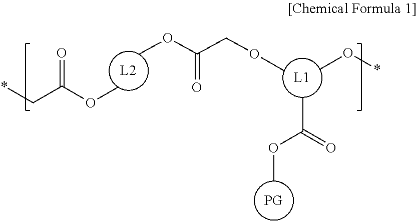
in which L1 is a trivalent substituted or unsubstituted aliphatic or aromatic hydrocarbon having 1 to 20 carbon atoms, L2 is a divalent substituted or unsubstituted aliphatic or aromatic hydrocarbon having 1 to 20 carbon atoms, PG, which serves as a protecting group, is hydrogen or a monovalent substituted or unsubstituted aliphatic or aromatic hydrocarbon having 1 to 10 carbon atoms, and * is an attachment position.

3. The photoresist composition of claim 1, wherein the photosensitive polymer comprises:
a repeating unit of Chemical Formula 4, 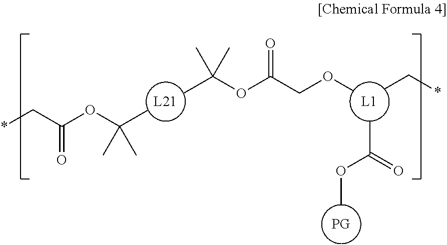
in which L1 is a trivalent substituted or unsubstituted aliphatic or aromatic hydrocarbon having 1 to 20 carbon atoms, L21 is a divalent substituted or unsubstituted aliphatic or aromatic hydrocarbon having 1 to 20 carbon atoms, PG, which serves as a protecting group, is hydrogen or a monovalent substituted or unsubstituted aliphatic or aromatic hydrocarbon having 1 to 10 carbon atoms, and * is an attachment position.

4. The photoresist composition of claim 1, wherein the photosensitive polymer comprises a repeating unit expressed as in following Chemical Formula 6, 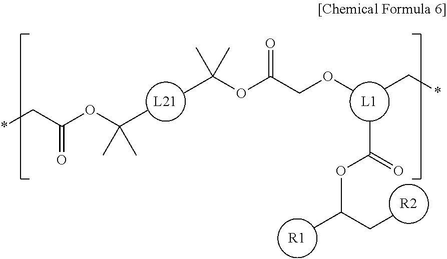
in which L1 is a trivalent substituted or unsubstituted aliphatic or aromatic hydrocarbon having 1 to 20 carbon atoms, L21 is a divalent substituted or unsubstituted aliphatic or aromatic hydrocarbon having 1 to 20 carbon atoms, PG, which serves as a protecting group, is hydrogen or a monovalent substituted or unsubstituted aliphatic or aromatic hydrocarbon having 1 to 10 carbon atoms, and * is an attachment position.

5. The photoresist composition of claim 1, wherein the photoacid generator comprises at least one of triphenylsulfonium triflate, triphenylsulfonium antimonate, triphenylsulfonium difluoroalkyl sulfonate, diphenyliodonium triflate, diphenyliodonium antimonate, methoxydiphenyliodonium triflate, di-t-butyldiphenyliodonium triflate, 2,6-dinitrobenzyl sulfonates, pyrogallol tris(alkylsulfonates), N-hydroxysuccinimide triflate, norbornene-dicarboximide-triflate, triphenylsulfonium nonaflate, diphenyliodonium nonaflate, methoxydiphenyliodonium nonaflate, di-t-butyldiphenyliodonium nonaflate, N-hydroxysuccinimide nonaflate, norbornene-dicarboximide-nonaflate, triphenylsulfonium perfluorobutanesulfonate, triphenylsulfonium perfluorooctanesulfonate (PFOS), diphenyliodonium PFOS, methoxydiphenyliodonium PFOS, di-t-butyldiphenyliodonium triflate, N-hydroxysuccinimide PFOS, norbornene-dicarboximide PFOS or any combination thereof.

6. The photoresist composition of claim 1, wherein the solvent comprises:
at least one of ether, alcohol, glycol ether, aromatic hydrocarbon compound, ketone, or ester.

7. The photoresist composition of claim 6, wherein the solvent comprises:
ethylene glycol monomethyl ether, ethylene glycol monoethyl ether, methylcellosolve acetate, ethylcellosolve acetate, diethylene glycol methyl ether, diethylene glycol ethyl ether, propylene glycol, propylene glycol methyl ether (PGME), propylene glycol methyl ether acetate (PGMEA), propylene glycol ethyl ether, propylene glycol ethyl ether acetate, propylene glycol propyl ether acetate, propylene glycol butyl ether, propylene glycol butyl ether acetate, ethanol, propanol, isopropyl alcohol, isobutyl alcohol, 4-methyl-2-pentanol (methyl isobutyl carbion: MIBC), hexanol, 1-methoxy-2-propanol, 1-ethoxy-2-propanol, ethylene glycol, propylene glycol, heptanone, propylene carbonate, butylene carbonate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, gamma-butyrolactone, methyl 2-hydroxyisobutyrate, methoxybenzene, n-butyl acetate, 1-methoxy-2-propyl acetate, methoxyethoxy propionate, ethoxyethoxy propionate, or any combination thereof.

8. The photoresist composition of claim 1, wherein the photoresist composition further comprises:
a base quencher to prevent acid generated from the photoacid generator from being diffused to a non-exposed area.

9. The photoresist composition of claim 8, wherein the base quencher comprises:
primary aliphatic amine, secondary aliphatic amine, tertiary aliphatic amine, aromatic amine, heterocyclic ring-containing amine, a nitrogen-containing compound having a carboxyl group, a nitrogen-containing compound having a sulfonyl group, a nitrogen-containing compound having a hydroxyl group, a nitrogen-containing compound having a hydroxyphenyl group, an alcoholic nitrogen-containing compound, an amide, an imide, a carbamate, or an ammonium salt.

10. The photoresist composition of claim 1, further comprising:
at least one selected from a surfactant, a dispersant, an absorbent, or a coupling agent.

11. A photosensitive polymer comprising:
a first main chain group, a second main chain group, and an acid-dissociative group attached to the first main chain group, and
at least one of the first main chain group or the second main chain group comprises an acid-dissociative functional group which is cleaved between the first main chain group and the second main chain group and between the first main chain group and the acid-dissociative group under presence of an acid catalyst, and
wherein the photosensitive polymer includes a repeating unit of Chemical Formula 1, 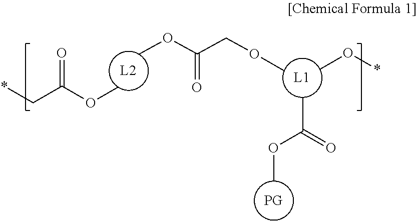
in which L1 is a trivalent substituted or unsubstituted aliphatic or aromatic hydrocarbon having 1 to 20 carbon atoms, L2 is a divalent substituted or unsubstituted aliphatic or aromatic hydrocarbon having 1 to 20 carbon atoms, PG, which serves as a protecting group, is hydrogen or a monovalent substituted or unsubstituted aliphatic or aromatic hydrocarbon having 1 to 10 carbon atoms, and * is an attachment position.

12. A method for fabricating a semiconductor device, the method comprising:
forming a photoresist layer on an underlayer;
exposing a first area of the photoresist layer;
forming a photoresist pattern by removing the first area of the photoresist layer using a developer; and
processing the underlayer using the photoresist pattern,
wherein the photoresist layer comprises:
a photosensitive polymer, a photoacid generator, and a solvent,
wherein the photosensitive polymer includes:
a first main chain group, a second main chain group, and an acid-dissociative group attached to the first main chain group, and
wherein at least one of the first main chain group or the second main chain group comprises an acid-dissociative functional group which is cleaved between the first main chain group and the second main chain group and between the first main chain group and the acid-dissociative group under presence of an acid catalyst.

13. The method of claim 12, wherein the photosensitive polymer comprises:
a repeating unit of Chemical Formula 1, 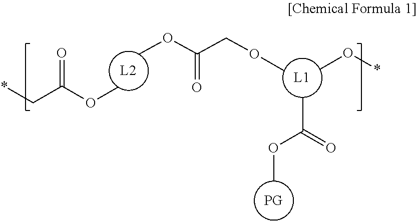
in which L1 is a trivalent substituted or unsubstituted aliphatic or aromatic hydrocarbon having 1 to 20 carbon atoms, L2 is a divalent substituted or unsubstituted aliphatic or aromatic hydrocarbon having 1 to 20 carbon atoms, PG, which serves as a protecting group, is hydrogen or a monovalent substituted or unsubstituted aliphatic or aromatic hydrocarbon having 1 to 10 carbon atoms, and * is an attachment position.

14. The method of claim 13, wherein the photosensitive polymer of Chemical Formula 1 is prepared through reaction as expressed in Chemical Equation 2, 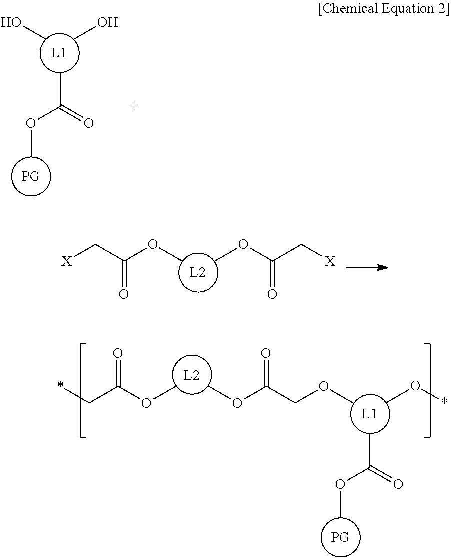
in which L1 is a trivalent substituted or unsubstituted aliphatic or aromatic hydrocarbon having 1 to 20 carbon atoms, L2 is a divalent substituted or unsubstituted aliphatic or aromatic hydrocarbon having 1 to 20 carbon atoms, PG, which serves as a protecting group, is hydrogen or a monovalent substituted or unsubstituted aliphatic or aromatic hydrocarbon having 1 to 10 carbon atoms, and * is an attachment position.

15. The method of claim 12, wherein the exposing of the first area of the photoresist layer comprises:
applying light having an extreme ultraviolet (EUV) wavelength band to the first area.

16. The method of claim 15, wherein light having the EUV wavelength band is one selected from a KrF excimer laser beam, an ArF excimer laser beam, an F2 excimer laser beam, and an EUV laser beam.

17. The method of claim 12, wherein the photosensitive polymer comprises a repeating unit of Chemical Formula 4, 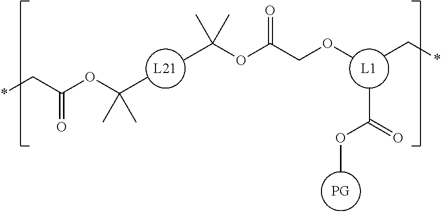
in which L1 is a trivalent substituted or unsubstituted aliphatic or aromatic hydrocarbon having 1 to 20 carbon atoms, L21 is a divalent substituted or unsubstituted aliphatic or aromatic hydrocarbon having 1 to 20 carbon atoms, PG, which serves as a protecting group, is hydrogen or a monovalent substituted or unsubstituted aliphatic or aromatic hydrocarbon having 1 to 10 carbon atoms, and * is an attachment position.

18. The method of claim 17, wherein the compound of Chemical Formula 4 is prepared through reaction as expressed in Chemical Equation 3, 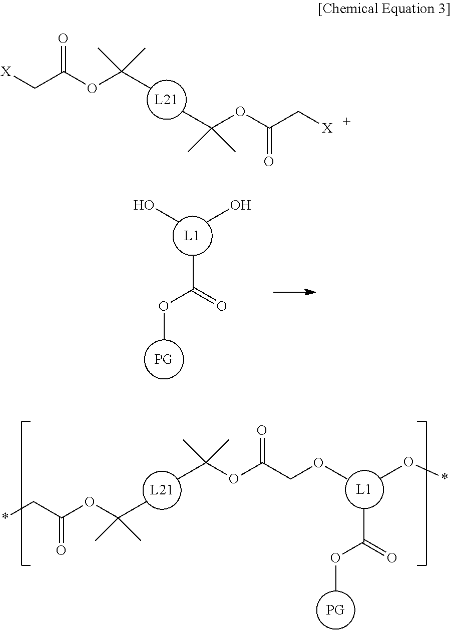
in which L1 is a trivalent substituted or unsubstituted aliphatic or aromatic hydrocarbon having 1 to 20 carbon atoms, L21 is a divalent substituted or unsubstituted aliphatic or aromatic hydrocarbon having 1 to 20 carbon atoms, PG, which serves as a protecting group, is hydrogen or a monovalent substituted or unsubstituted aliphatic or aromatic hydrocarbon having 1 to 10 carbon atoms, and * is an attachment position.

19. The method of claim 12, wherein the photosensitive polymer comprises:
a repeating unit of Chemical Formula 6, 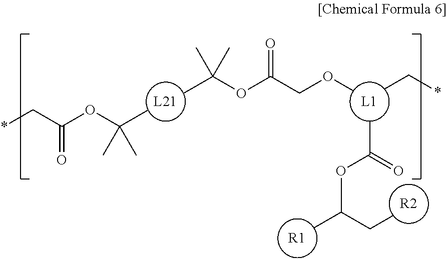
in which L1 is a trivalent substituted or unsubstituted aliphatic or aromatic hydrocarbon having 1 to 20 carbon atoms, L21 is a divalent substituted or unsubstituted aliphatic or aromatic hydrocarbon having 1 to 20 carbon atoms, PG, which serves as a protecting group, is hydrogen or a monovalent substituted or unsubstituted aliphatic or aromatic hydrocarbon having 1 to 10 carbon atoms, and * is an attachment position.

20. The method of claim 12, further comprising:
performing an annealing process for the photoresist layer, after forming the photoresist layer.
